(19) United States
(12) Patent Application Publication
(10) Pub. No.: US 2024/0405502 A1
(43) Pub. Date: Dec. 5, 2024

(54) LASER APPARATUS, METHOD FOR MEASURING SPECTRAL LINEWIDTH, AND METHOD FOR MANUFACTURING ELECTRONIC DEVICES

(71) Applicant: Gigaphoton Inc., Tochigi (JP)

(72) Inventors: Kazuhiro SUZUKI, Oyama-shi (JP); Hiroshi TANAKA, Oyama-shi (JP)

(73) Assignee: Gigaphoton Inc., Tochigi (JP)

(21) Appl. No.: 18/807,455

(22) Filed: Aug. 16, 2024

Related U.S. Application Data
(63) Continuation of application No. PCT/JP2022/008766, filed on Mar. 2, 2022.

(51) Int. Cl. H01S 3/10; G03F 7/20; H01S 3/13

(52) U.S. Cl. CPC H01S 3/10015; G03F 7/2006; H01S 3/1305

(57) ABSTRACT

A laser apparatus includes: a laser oscillator including a wavelength adjuster and configured to output pulse laser light having a center wavelength adjusted by the wavelength adjuster; a spectrum monitor configured to generate data on a spectrum of the pulse laser light; and a processor configured to control the wavelength adjuster in such a way that the center wavelength of the pulse laser light changes in accordance with a target wavelength that periodically changes to each of multiple values including first and second wavelengths, calculate a first spectral linewidth from data on spectra of multiple pulses each having the first wavelength as the target wavelength, and calculate a second spectral linewidth from data on spectra of multiple pulses each having the second wavelength as the target wavelength.

### CROSS-REFERENCE TO RELATED APPLICATIONS

The present application is a continuation application of International Application No. PCT/JP2022/008766, filed on Mar. 2, 2022, the entire contents of which are hereby incorporated by reference.

### BACKGROUND

### 1. Technical Field

The present disclosure relates to a laser apparatus, a method for measuring a spectral linewidth, and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light output from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] U.S. Patent application Publication No. 2005/083983

### SUMMARY

A laser apparatus according to an aspect of the present disclosure includes: a laser oscillator including a wavelength adjuster and configured to output pulse laser light having a center wavelength adjusted by the wavelength adjuster; a spectrum monitor configured to generate data on a spectrum of the pulse laser light; and a processor configured to control the wavelength adjuster in such a way that the center wavelength of the pulse laser light changes in accordance with a target wavelength that periodically changes to each of multiple values including first and second wavelengths, calculate a first spectral linewidth from data on spectra of multiple pulses each having the first wavelength as the target wavelength, and calculate a second spectral linewidth from data on spectra of multiple pulses each having the second wavelength as the target wavelength.

A method for measuring a spectral linewidth according to another aspect of the present disclosure includes: changing a center wavelength of pulse laser light in accordance with a target wavelength that periodically changes to each of multiple values including first and second wavelengths; calculating a first spectral linewidth from data on spectra of multiple pulses each having the first wavelength as the target wavelength; and calculating a second spectral linewidth from data on spectra of multiple pulses each having the second wavelength as the target wavelength.

A method for manufacturing electronic device according to another aspect of the present disclosure includes: generating pulse laser light by using a laser apparatus; outputting the pulse laser light to an exposure apparatus; and exposing a photosensitive substrate with the pulse laser light in the exposure apparatus to manufacture the electronic devices, and the laser apparatus includes a laser oscillator including a wavelength adjuster and configured to output the pulse laser light having a center wavelength adjusted by the wavelength adjuster, a spectrum monitor configured to generate data on a spectrum of the pulse laser light, and a processor configured to control the wavelength adjuster in such a way that the center wavelength of the pulse laser light changes in accordance with a target wavelength that periodically changes to each of multiple values including first and second wavelengths, calculate a first spectral linewidth from data on spectra of multiple pulses each having the first wavelength as the target wavelength, and calculate a second spectral linewidth from data on spectra of multiple pulses each having the second wavelength as the target wavelength.

### BRIEF DESCRIPTION OF DRAWINGS

Some embodiments of the present disclosure will be described below only by way of example with reference to the accompanying drawings.

FIG. 1 schematically shows the configuration of an exposure system in Comparative Example.

FIG. 2 schematically shows the configuration of a laser apparatus according to Comparative Example.

FIG. 3 is a time chart showing a method for measuring a spectral linewidth according to Comparative Example.

FIG. 4 is a flowchart showing the method for measuring the spectral linewidth according to Comparative Example.

FIG. 5 shows an example of a spectral waveform used to explain E95.

FIG. 6 is a graph showing an example of periodically changing a target wavelength of pulse laser light.

FIG. 7 shows the spectral waveform of the pulse laser light for each pulse generated when the target wavelength is periodically changed.

FIG. 8 schematically shows the configuration of a laser apparatus according to a first embodiment.

FIG. 9 is a time chart showing a method for measuring the spectral linewidth according to the first embodiment.

FIG. 10 is a flowchart showing the method for measuring the spectral linewidth according to the first embodiment.

FIG. 11 is a time chart showing a method for measuring the spectral linewidth according to a second embodiment.

FIG. 12 is a time chart showing a method for measuring the spectral linewidth according to a third embodiment.

### DETAILED DESCRIPTION

### Contents

1. Comparative Example
1.1 Configuration of exposure apparatus 100
1.2 Operation of exposure apparatus 100
1.3 Configuration of laser apparatus 1
1.3.1. Laser oscillator 20
1.3.2 Monitor module 16
1.3.3 Various processing apparatuses
1.4 Operation
1.4.1 Laser control processor 30
1.4.2. Laser oscillator 20
1.4.3 Monitor module 16
1.4.4 Wavelength measurement control processor 50
1.4.5 Spectrum measurement control processor 60
1.5 Problems with Comparative Example
2. Embodiment in which fringe waveforms of multiple pulses are accumulated for each target wavelength
2.1 Configuration
2.2 Operation
2.3 Effects
3. Embodiment using fringe waveforms of pulses excluding start pulses of burst
3.1 Operation
3.2 Effects
4. Embodiment using fringe waveforms of consecutive pulses
4.1 Operation
4.2 Effects
5. Others

Embodiments of the present disclosure will be described below in detail with reference to the drawings. The embodiments described below show some examples of the present disclosure and are not intended to limit the content of the present disclosure. Furthermore, all configurations and operations described in the embodiments are not necessarily essential as configurations and operations in the present disclosure. The same elements have the same reference character, and no redundant description of the same elements will be made.

### 1. Comparative Example

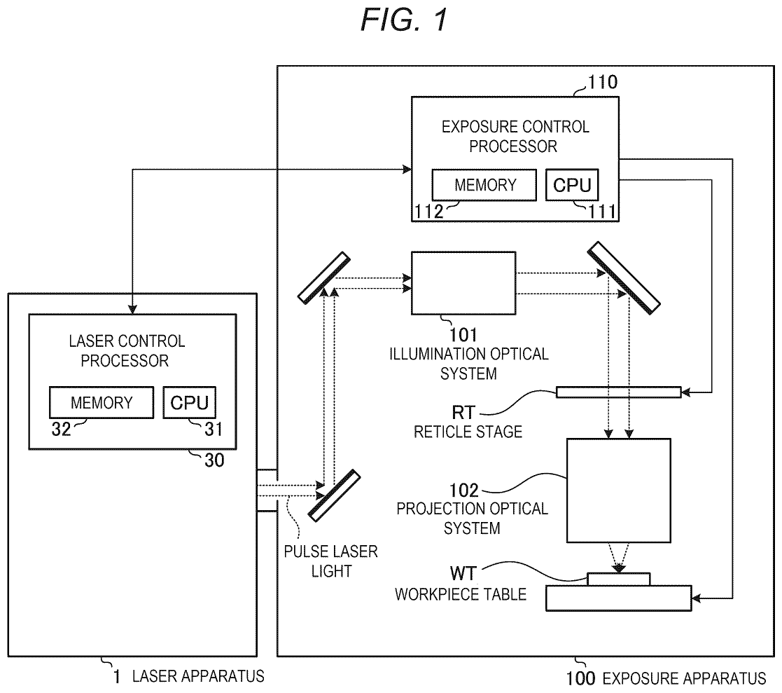

FIG. 1 schematically shows the configuration of an exposure system in Comparative Example. Comparative Example in the present disclosure is an aspect that the applicant is aware of as known only by the applicant, and is not a publicly known example that the applicant is self-aware of.

The exposure system includes a laser apparatus 1 and an exposure apparatus 100. The exposure apparatus 100 is an example of the external apparatus in the present disclosure. The laser apparatus 1 includes a laser control processor 30. The laser control processor 30 is a processing apparatus including a memory 32, which stores a control program, and a CPU (central processing unit) 31, which executes the control program. The laser control processor 30 is particularly configured or programmed to carry out a variety of processes described in the present disclosure. The laser control processor 30 constitutes the processor in the present disclosure. The laser apparatus 1 is configured to output pulse laser light toward the exposure apparatus 100.

### 1.1 Configuration of Exposure Apparatus 100

The exposure apparatus 100 includes an illumination optical system 101, a projection optical system 102, and an exposure control processor 110.

The illumination optical system 101 illuminates a reticle pattern of a reticle that is not shown but is placed on a reticle stage RT with the pulse laser light having entered the illumination optical system 101 from the laser apparatus 1.

The projection optical system 102 performs reduction projection on the pulse laser light having passed through the reticle to bring the pulse laser light into focus at a workpiece that is not shown but is placed on a workpiece table WT. The workpiece is a photosensitive substrate, such as a semiconductor wafer coated with a photoresist film.

The exposure control processor 110 is a processing apparatus including a memory 112, which stores a control program, and a CPU 111, which executes the control program. The exposure control processor 110 is particularly configured or programmed to carry out a variety of processes described in the present disclosure. The exposure control processor 110 oversees and controls the exposure apparatus 100 and transmits and receives a variety of data and signals to and from the laser control processor 30.

### 1.2 Operation of Exposure Apparatus 100

The exposure control processor 110 transmits data for setting a target wavelength, a target spectral linewidth, and target pulse energy, and a trigger signal to the laser control processor 30. The laser control processor 30 controls the laser apparatus 1 in accordance with the data and the signal.

The exposure control processor 110 translates the reticle stage RT and the workpiece table WT in opposite directions in synchronization with each other. The workpiece is thus exposed to the pulse laser light having reflected the reticle pattern.

The exposure step described above causes the reticle pattern to be transferred to the semiconductor wafer. The following multiple steps allow manufacture of electronic devices.

### 1.3 Configuration of Laser Apparatus 1

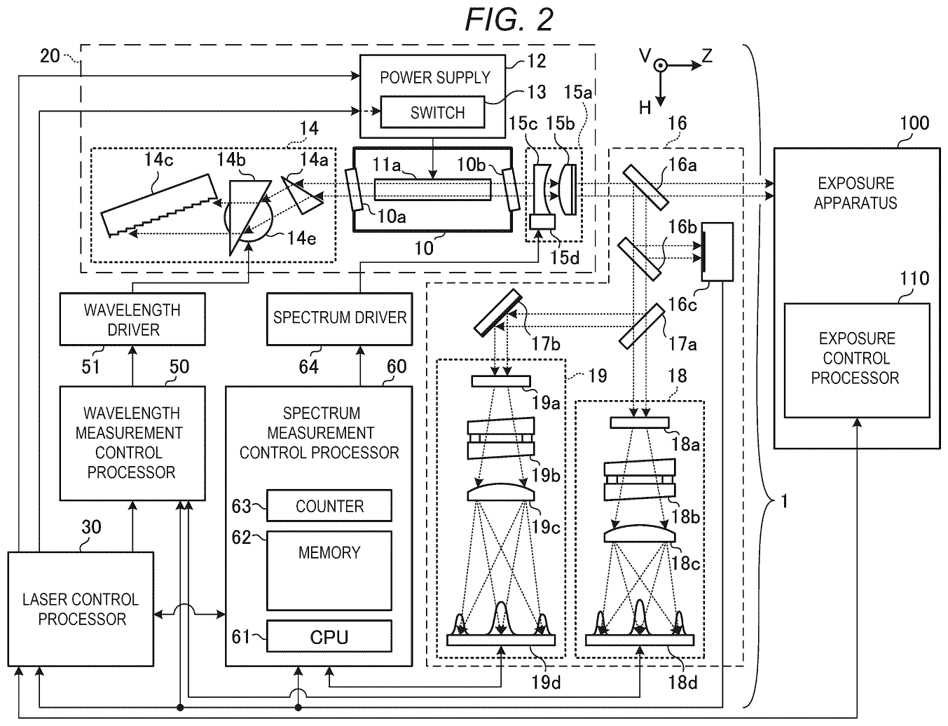

FIG. 2 schematically shows the configuration of the laser apparatus 1 according to Comparative Example. The laser apparatus 1 includes a laser oscillator 20, a monitor module 16, the laser control processor 30, a wavelength measurement control processor 50, and a spectrum measurement control processor 60. The laser apparatus 1 can be connected to the exposure apparatus 100. The wavelength measurement control processor 50 and the spectrum measurement control processor 60 constitute the processor in the present disclosure.

### 1.3.1. Laser Oscillator 20

The laser oscillator 20 includes a laser chamber 10, a discharge electrode 11a, a power supply 12, a line narrowing module 14, and a spectrum adjuster 15a.

The line narrowing module 14 and the spectrum adjuster 15a form a laser resonator. The laser chamber 10 is disposed in the optical path of the laser resonator. Windows 10a and 10b are provided at both ends of the laser chamber 10. The discharge electrode 11a and a discharge electrode that is not shown but is paired therewith are disposed in the laser chamber 10. The discharge electrode that is not shown is located so as to coincide with the discharge electrode 11a in the direction of a V-axis perpendicular to the plane of view. The laser chamber 10 is filled with a laser gas containing, for example, an argon or krypton gas as a rare gas, a fluorine gas as a halogen gas, and a neon gas as a buffer gas.

The power supply 12 includes a switch 13 and is connected to the discharge electrode 11a and a charger that is not shown.

The line narrowing module 14 includes multiple prisms 14a and 14b and a grating 14c. The prisms 14a and 14b are disposed in this order in the optical path of the light having exited via the window 10a. The surface on which the light is incident on each of the prisms 14a and 14b and the surface via which the light exits are both parallel to the V-axis. The prism 14b is supported by a rotary stage 14e. The rotary stage 14e is connected to a wavelength driver 51. The rotary stage 14e corresponds to the wavelength adjuster in the present disclosure.

The grating 14c is disposed in the optical path of the light having passed through the prisms 14a and 14b. The direction of the grooves of the grating 14c is parallel to the V-axis.

The spectrum adjuster 15a includes a cylindrical plano-convex lens 15b and a cylindrical plano-concave lens 15c. The cylindrical plano-concave lens 15c is located between the laser chamber 10 and the cylindrical plano-convex lens 15b. The cylindrical plano-concave lens 15c is supported by a linear stage 15d. The linear stage 15d is connected to a spectrum driver 64.

The cylindrical plano-convex lens 15b and the cylindrical plano-concave lens 15c are so disposed that the convex surface of the cylindrical plano-convex lens 15b and the concave surface of the cylindrical plano-concave lens 15c face each other. The convex surface of the cylindrical plano-convex lens 15b and the concave surface of the cylindrical plano-concave lens 15c each have a focal axis parallel to the direction of the V-axis. The planar surface located opposite to the convex surface of the cylindrical plano-convex lens 15b is coated with a partially reflective film.

### 1.3.2 Monitor Module 16

The monitor module 16 is disposed in the optical path of the pulse laser light between the spectrum adjuster 15a and the exposure apparatus 100. The monitor module 16 includes beam splitters 16a, 16b, and 17a, an energy sensor 16c, a highly reflective mirror 17b, a wavelength monitor 18, and a spectrum monitor 19.

The beam splitter 16a is located in the optical path of the pulse laser light output from the spectrum adjuster 15a. The beam splitter 16a is configured to transmit part of the pulse laser light at high transmittance toward the exposure apparatus 100 and reflect the other part of the pulse laser light. The beam splitter 16b is located in the optical path of the pulse laser light reflected off the beam splitter 16a. The energy sensor 16c is located in the optical path of the pulse laser light reflected off the beam splitter 16b.

The beam splitter 17a is located in the optical path of the pulse laser light having passed through the beam splitter 16b. The highly reflective mirror 17b is located in the optical path of the pulse laser light reflected off the beam splitter 17a.

The wavelength monitor 18 is disposed in the optical path of the pulse laser light having passed through the beam splitter 17a. The wavelength monitor 18 includes a diffusion plate 18a, an etalon 18b, a focusing lens 18c, and a line sensor 18d.

The diffusion plate 18a is located in the optical path of the pulse laser light having passed through the beam splitter 17a. The diffusion plate 18a has a large number of protrusions and recesses at a surface thereof and is configured to transmit and diffuse the pulse laser light.

The etalon 18b is located in the optical path of the pulse laser light having passed through the diffusion plate 18a. The etalon 18b includes two partially reflective mirrors. The two partially reflective mirrors face each other with an air gap having a predetermined thickness therebetween and are bonded to each other via a spacer.

The focusing lens 18c is located in the optical path of the pulse laser light having passed through the etalon 18b.

The line sensor 18d is located at the focal plane of the focusing lens 18c in the optical path of the pulse laser light having passed through the focusing lens 18c. The line sensor 18d is a light distribution detecting sensor including a large number of light receivers arranged in one dimension. In place of the line sensor 18d, a photodiode array may be used, or an image sensor including a large number of light receivers arranged two-dimensionally may instead be used.

The line sensor 18d receives interference fringes formed by the etalon 18b and the focusing lens 18c. The interference fringes form an interference pattern produced by the pulse laser light and have the shape of concentric circles, and the square of the distance from the center of the concentric circles is proportional to the change in the wavelength of the pulse laser light.

The spectrum monitor 19 is disposed in the optical path of the pulse laser light reflected off the highly reflective mirror 17b. The spectrum monitor 19 includes a diffusion plate 19a, an etalon 19b, a focusing lens 19c, and a line sensor 19d. The components described above are the same as the diffusion plate 18a, the etalon 18b, the focusing lens 18c, and the line sensor 18d incorporated in the wavelength monitor 18. Note, however, that the etalon 19b has a free spectral range narrower than that of the etalon 18b. Furthermore, note that the focusing lens 19c has a focal length longer than that of the focusing lens 18c.

### 1.3.3 Various Processing Apparatuses

The spectrum measurement control processor 60 is a processing apparatus including a memory 62, which stores a control program, a CPU 61, which executes the control program, and a counter 63. The spectrum measurement control processor 60 is specially configured or programmed to carry out a variety of processes described in the present disclosure.

The memory 62 also stores a variety of data used to calculate the spectral linewidth. The variety of data include an apparatus function of the spectrum monitor 19. The counter 63 counts the number of pulses of the pulse laser light by counting the number of times an electric signal containing pulse energy data output from the energy sensor 16c has been received. The counter 63 may instead count the number of pulses of the pulse laser light by counting an oscillation trigger signal output from the laser control processor 30.

The wavelength measurement control processor 50 is a processing apparatus including a memory that is not shown but stores a control program, a CPU that is not shown but executes the control program, and a counter that is not shown. The wavelength measurement control processor 50 is specially configured or programmed to carry out a variety of processes described in the present disclosure. The counter incorporated in the wavelength measurement control processor 50 counts the number of pulses of the pulse laser light, as the counter 63 does.

In the present disclosure, the laser control processor 30, the wavelength measurement control processor 50, and the spectrum measurement control processor 60 are described as separate components, but the laser control processor 30 may also serve as the wavelength measurement control processor 50 and the spectrum measurement control processor 60.

### 1.4 Operation

### 1.4.1 Laser Control Processor 30

The laser control processor 30 transmits to the power supply 12 data for setting an application voltage to be applied to the discharge electrode 11a based on the data for setting the target pulse energy received from the exposure control processor 110. The laser control processor 30 transmits the data for setting the target wavelength and the target spectral linewidth received from the exposure control processor 110 to the wavelength measurement control processor 50 and the spectrum measurement control processor 60, respectively. The laser control processor 30 further transmits an oscillation trigger signal based on the trigger signal received from the exposure control processor 110 to the switch 13 incorporated in the power supply 12.

### 1.4.2. Laser Oscillator 20

The switch 13 is turned on when the switch 13 receives the oscillation trigger signal from the laser control processor 30. When the switch 13 is turned on, the power supply 12 generates a pulse-shaped high voltage from the electric energy charged in the charger that is not shown and applies the high voltage to the discharge electrode 11a.

When the high voltage is applied to the discharge electrode 11a, discharge occurs in the laser chamber 10. The energy of the discharge excites a laser medium in the laser chamber 10, and the excited laser medium transitions to a high energy level. Thereafter, when the excited laser medium transitions to a low energy level, the laser medium emits light having a wavelength according to the difference between the energy levels.

The light generated inside the laser chamber 10 exits out of the laser chamber 10 via the windows 10a and 10b. The light having exited via the window 10a of the laser chamber 10 is enlarged in terms of beam width by the prisms 14a and 14b and is then incident on the grating 14c.

The light incident from the prisms 14a and 14b on the grating 14c is reflected off and diffracted by multiple grooves of the grating 14c in the direction according to the wavelength of the light.

The prisms 14a and 14b reduce the beam width of the diffracted light from the grating 14c and causes the light to return to the laser chamber 10 via the window 10a.

The spectrum adjuster 15a transmits and outputs part of the light having exited via the window 10b of the laser chamber 10 and reflects the other part of the light back into the laser chamber 10 via the window 10b.

The light output from the laser chamber 10 thus travels back and forth between the line narrowing module 14 and the spectrum adjuster 15a and is amplified whenever passing through the discharge space inside the laser chamber 10. The light undergoes the line narrowing operation whenever deflected back by the line narrowing module 14. The light thus having undergone the laser oscillation and line narrowing in the laser oscillator 20 is output as the pulse laser light from the spectrum adjuster 15a.

The rotary stage 14e incorporated in the line narrowing module 14 rotates the prism 14b around an axis parallel to the V-axis in accordance with a drive signal output from the wavelength driver 51. Rotating the prism 14b causes adjustment of the wavelength selected by the line narrowing module 14, and hence adjustment of the center wavelength of the pulse laser light.

The linear stage 15d incorporated in the spectrum adjuster 15a moves the cylindrical plano-concave lens 15c along the optical path between the laser chamber 10 and the cylindrical plano-convex lens 15b in accordance with a drive signal output from the spectrum driver 64. The movement changes wavefront of the light traveling from the spectrum adjuster 15a toward the line narrowing module 14. The change in the wavefront adjusts the spectral waveform and spectral linewidth of the pulse laser light.

### 1.4.3 Monitor Module 16

The energy sensor 16c detects the pulse energy of the pulse laser light and outputs the data on the pulse energy to the laser control processor 30, the wavelength measurement control processor 50, and the spectrum measurement control processor 60. The data on the pulse energy is used by the laser control processor 30 to perform feedback control on the data for setting the application voltage to be applied to the discharge electrode 11a. The electric signal containing the data on the pulse energy can be used by the wavelength measurement control processor 50 and the spectrum measurement control processor 60 to each count the number of pulses of the pulse laser light.

In the wavelength monitor 18, the waveform of the interference fringes is generated from the amount of light in each of the light receivers incorporated in the line sensor 18d having received the interference fringes. The waveform of the interference fringes is also called a fringe waveform. The line sensor 18d may generate the fringe waveform by successively performing exposure for a fixed period to accumulate the amount of light in each of the light receivers over multiple pulses contained in the pulse laser light.

In the spectrum monitor 19, the fringe waveform is generated from the amount of light in each of the light receivers incorporated in the line sensor 19d having received the interference fringes. The line sensor 19d may generate the fringe waveform by successively performing exposure for a fixed period to accumulate the amount of light in each of the light receivers over multiple pulses contained in the pulse laser light.

### 1.4.4 Wavelength Measurement Control Processor 50

The wavelength measurement control processor 50 counts the number of pulses of the pulse laser light, and transmits a data output trigger to the wavelength monitor 18 whenever the number of accumulated pulses reaches a fixed number. The wavelength measurement control processor 50 receives the fringe waveform output from the wavelength monitor 18 in accordance with the data output trigger. The wavelength measurement control processor 50 uses the fringe waveform to calculate the center wavelength of the pulse laser light.

The wavelength measurement control processor 50 performs feedback control on the center wavelength of the pulse laser light by outputting a wavelength control signal to the wavelength driver 51 based on the calculated center wavelength and the target wavelength received from the laser control processor 30.

### 1.4.5 Spectrum Measurement Control Processor 60

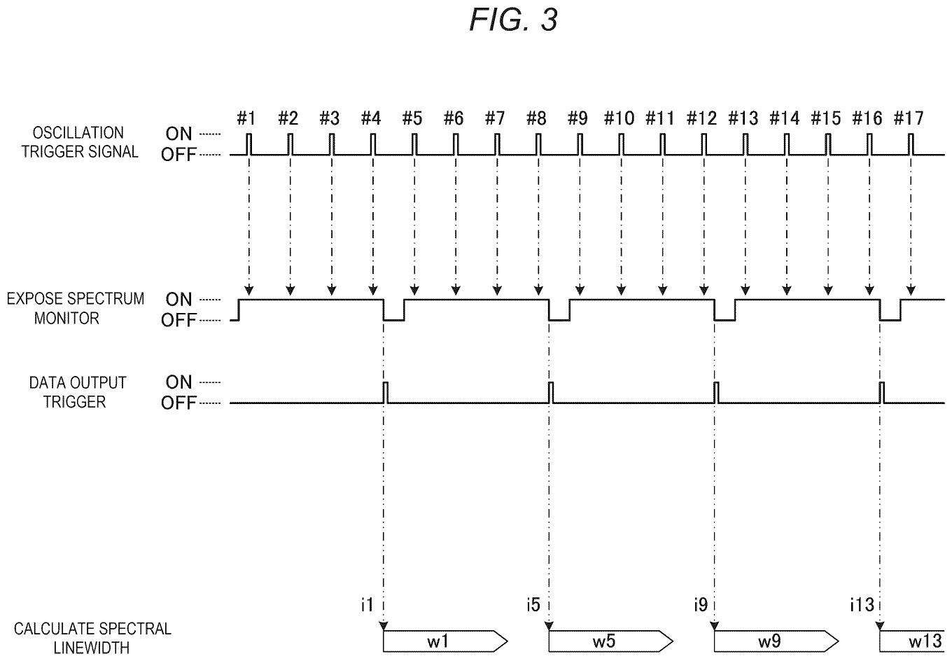

FIG. 3 is a time chart showing a method for measuring a spectral linewidth according to Comparative Example. Individual pulses of the pulse laser light are generated in accordance with the oscillation trigger signal, and the line sensor 19d is exposed to the pulse laser light in the spectrum monitor 19 to generate a fringe waveform as a result of accumulation of the amount of light over the multiple pulses.

The spectrum measurement control processor 60 counts the number of pulses of the pulse laser light, and outputs the data output trigger to the spectrum monitor 19 whenever the number of accumulated pulses reaches n. The number n of accumulated pulses is, for example, four.

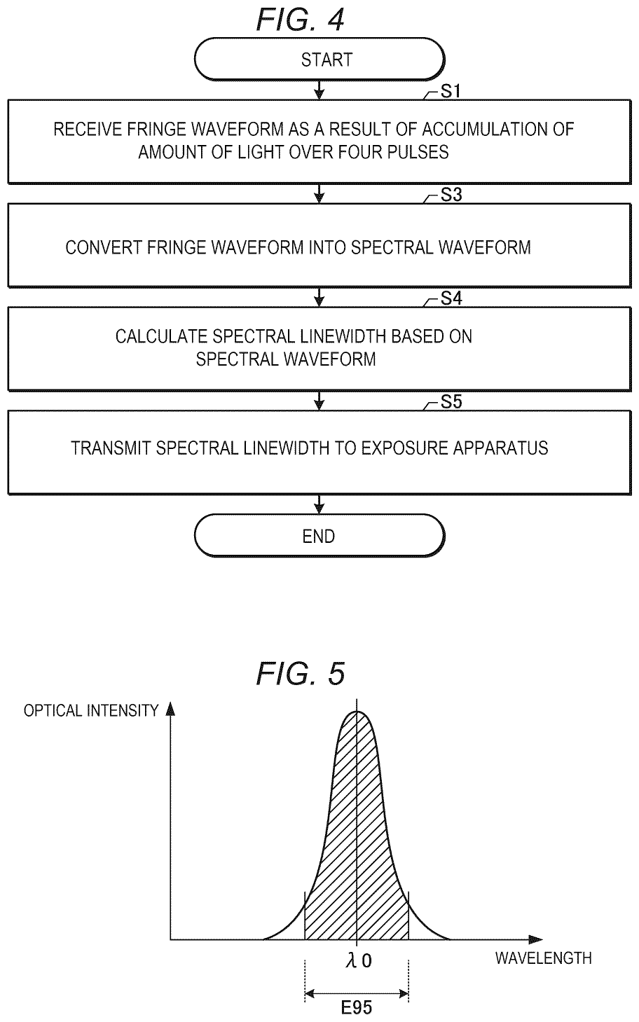

FIG. 4 is a flowchart showing the method for measuring the spectral linewidth according to Comparative Example. The process shown in FIG. 4 is carried out whenever the pulse laser light including the number n of accumulated pulses is output.

In step S1, the spectrum measurement control processor 60 receives from the spectrum monitor 19 the fringe waveform as a result of accumulation of the amount of light over four pulses. For example, the spectrum measurement control processor 60 receives a fringe waveform i1 as a result of accumulation of the amounts of light over pulses #1 to #4 shown in FIG. 3.

In step S3, the spectrum measurement control processor 60 carries out the following process to convert the fringe waveform into a spectral waveform. A portion of the fringe waveform that corresponds to the free spectral range is first extracted. The portion extracted from the fringe waveform indicates the relationship between the distance from the center of the concentric circles, which constitute the interference fringes, and the optical intensity. The spectrum measurement control processor 60 then performs coordinate transformation on the waveform into the relationship between the wavelength and the optical intensity. The coordinate transformation of a portion of the fringe waveform into the relationship between the wavelength and the optical intensity is called mapping to a wavelength space. The coordinate transformation allows the spectrum measurement control processor 60 to acquire a spectral waveform. Data on the fringe waveform and data on the spectral waveform are each an example of the spectrum data in the present disclosure.

The case where the spectrum measurement control processor 60 converts a fringe waveform into a spectral waveform has been described, but the present disclosure is not limited thereto. The spectrum monitor 19 may convert a fringe waveform into a spectral waveform.

In step S4, the spectrum measurement control processor 60 calculates the spectral linewidth based on the spectral waveform. For example, a spectral linewidth w1 is calculated based on the spectral waveform produced from the fringe waveform i1 shown in FIG. 3.

The calculation of the spectral linewidth may include estimating a true spectral waveform having entered the spectrum monitor 19 by performing deconvolution integration on the spectral waveform using the apparatus function of the spectrum monitor 19, and calculating the spectral linewidth from the estimated true spectral waveform. The deconvolution integration may require a calculation period longer than the repetition cycle of the pulse laser light. FIG. 3 shows an example of the period required to calculate the spectral linewidths w1, w5, and so on in the form of a horizontal length of a pentagonal contour. During one cycle of the spectral linewidth calculation, another multiple pulses of the pulse laser light are output.

The spectral linewidth may be the full width at half maximum or may be an index called E95.

FIG. 5 shows an example of a spectral waveform used to explain E95. The horizontal axis of FIG. 5 represents the wavelength, and the vertical axis of FIG. 5 represents the optical intensity. The full width of the portion that occupies 95% of the total energy of the spectrum with the center wavelength λ0 as the center is defined as E95.

The spectrum measurement control processor 60 transmits the spectral linewidth to the laser control processor 30.

In step S5 in FIG. 4, the laser control processor 30 transmits the spectral linewidth to the exposure apparatus 100. After step S5, the laser control processor 30 terminates the process of the flowchart.

A pulse #5 and subsequent pulses shown in FIG. 3 are the same as the pulses #1 to #4.

1.5 Problems with Comparative Example

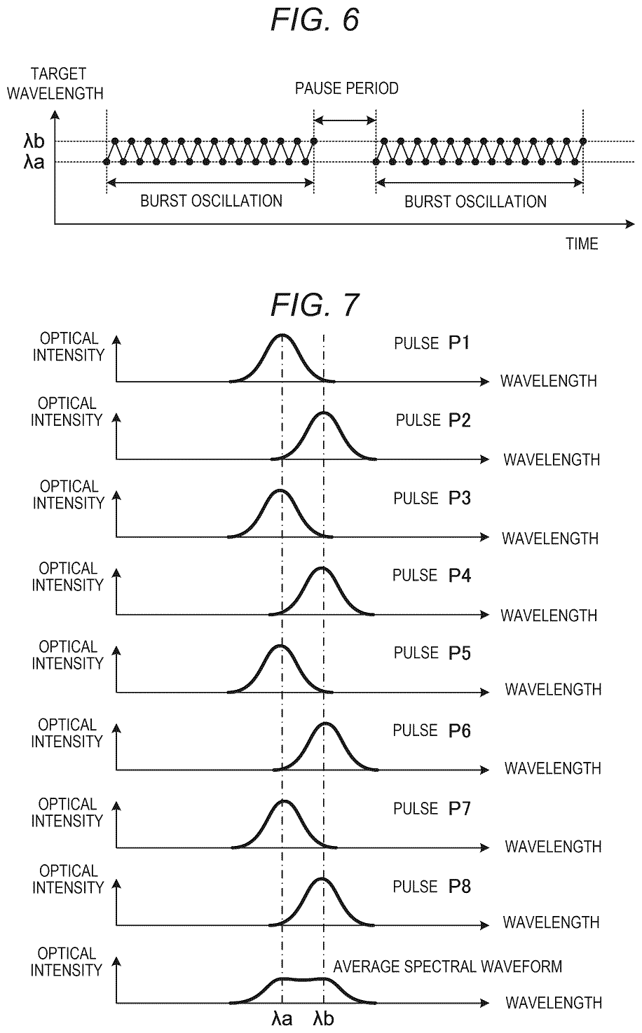

FIG. 6 is a graph showing an example of periodically changing a target wavelength of pulse laser light.

The laser oscillator 20 performs the laser oscillation at a repetition frequency higher than or equal to a certain value over a certain period in accordance with the trigger signal from the exposure control processor 110. Performing the laser oscillation at a repetition frequency higher than or equal to a certain value and outputting pulse laser light is called “burst oscillation”.

When the exposure control processor 110 causes the trigger signal to pause, the laser oscillator 20 causes the burst oscillation to pause. The laser oscillator 20 then performs the burst oscillation again in accordance with the trigger signal from the exposure control processor 110. The period between first burst oscillation and subsequent second burst oscillation is called a “pause period”.

The period for which the burst oscillation is performed corresponds, for example, to the period for which one exposure area of a semiconductor wafer is exposed to the pulse laser light in the exposure apparatus 100. The pause period corresponds, for example, to a period for which the position where an image of the reticle pattern is brought into focus is moved from one exposure area to another in the exposure apparatus 100, or a period for which the semiconductor wafer is replaced with another. Adjustment oscillation for adjusting a variety of parameters may be performed during the pause period.

The center wavelength of the pulse laser light can be periodically changed by periodically changing the target wavelength to each of multiple values including a first wavelength λa and a second wavelength λb and controlling the rotary stage 14e in accordance with the changed target wavelength. The focal length in the exposure apparatus 100 depends on the wavelength of the pulse laser light. The periodic change in the center wavelength periodically changes the position where the pulse laser light is brought into focus in the direction of the optical path axis of the pulse laser light, so that the depth of focus can be practically increased. For example, even when a photoresist film having a large thickness is exposed to the pulse laser light, the image formation performance can be maintained in the thickness direction of the photoresist film. Instead, a photoresist profile indicating the cross-sectional shape of a developed photoresist film can be adjusted.

Periodically changing the target wavelength, however, causes inappropriate measurement of the spectral linewidth in some cases. Such cases will be described with reference to FIG. 7.

FIG. 7 shows the spectral waveform of the pulse laser light for each pulse generated when the target wavelength is periodically changed. FIG. 7 shows a case where pulses P1 to P8 are output in ascending order of the number of the pulses while switching the target wavelength between the first wavelength λa and the second wavelength λb on a pulse basis. The pulses P1, P3, P5, and P7 have the first wavelength λa as the target wavelength, and the pulses P2, P4, P6, and P8 have the second wavelength λb as the target wavelength.

The average spectral waveform shown at the bottom of FIG. 7 is the result of division of the optical intensity of the accumulated spectral waveform as a result of accumulation of the spectral waveforms of the pulses P1 to P8 by 8, which is the number of pulses. When the spectral waveforms are averaged, the average spectral waveform of the individual pulses may have a shape significantly different from the shape of the spectral waveform of each of the individual pulses. The average spectral waveform may have peaks near the first wavelength λa and near the second wavelength λb, or may have a substantially flat top shape between the first wavelength λa and the second wavelength λb. Such an average spectral waveform may be useful, for example, for assessing the distribution of the wavelengths of multiple pulses radiated to one location on a semiconductor wafer. An average spectral waveform significantly different from the spectral waveform of each of the individual pulses may, however, not be useful, for example, for appropriately controlling the spectrum adjuster 15a.

### 2. Embodiment in which Fringe Waveforms of Multiple Pulses are Accumulated for each Target Wavelength

### 2.1 Configuration

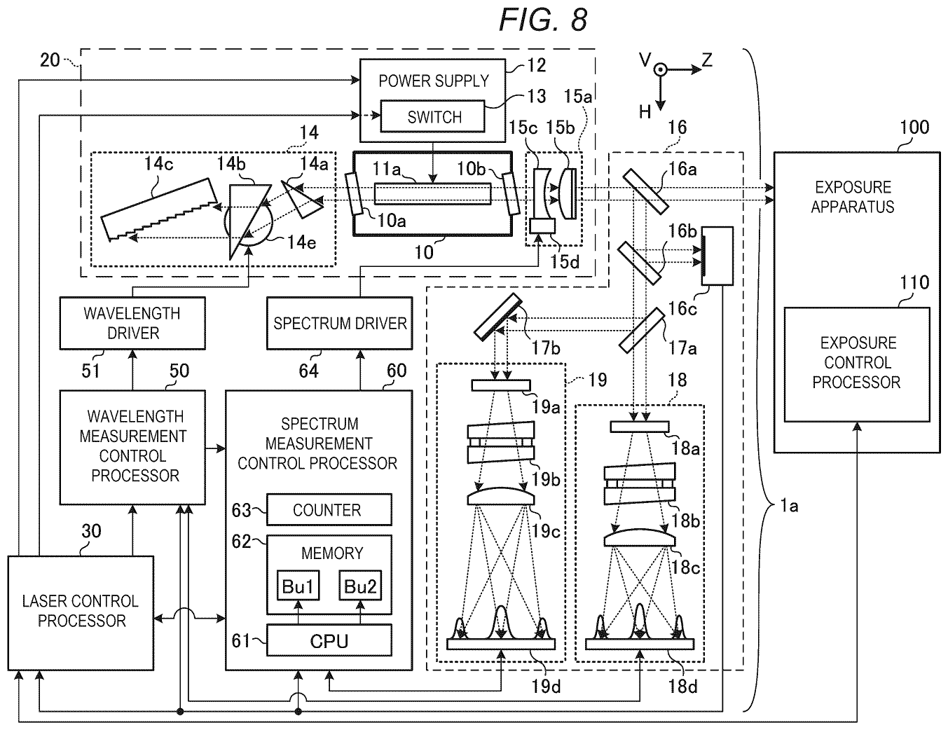

FIG. 8 schematically shows the configuration of a laser apparatus 1a according to a first embodiment. The laser apparatus 1a according to the first embodiment differs from the laser apparatus 1 according to Comparative Example in the points below.

The memory 62 of the spectrum measurement control processor 60 includes a first buffer Bu1 and a second buffer Bu2.

The wavelength measurement control processor 50 transmits the wavelength control signal to be transmitted to the wavelength driver 51 also to the spectrum measurement control processor 60.

The first buffer Bu1 and the second buffer Bu2 are each a memory region that temporarily stores an accumulated fringe waveform as a result of accumulation of fringe waveforms. The spectrum measurement control processor 60 evaluates whether a fringe waveform received from the spectrum monitor 19 is the fringe waveform of a pulse having either the first wavelength λa or the second wavelength λb as the target wavelength. The evaluation can be made based on the wavelength control signal representing the content of the control of the rotary stage 14e performed by the wavelength measurement control processor 50. The CPU 61 incorporated in the spectrum measurement control processor 60 or a selector that is not shown but is connected to the CPU 61 accumulates fringe waveforms and stores the accumulated fringe waveform in the first buffer Bu1 or the second buffer Bu2 in accordance with the result of the evaluation. The number of buffers is not limited to two, and more buffers may be provided in accordance with the number of target wavelengths.

### 2.2 Operation

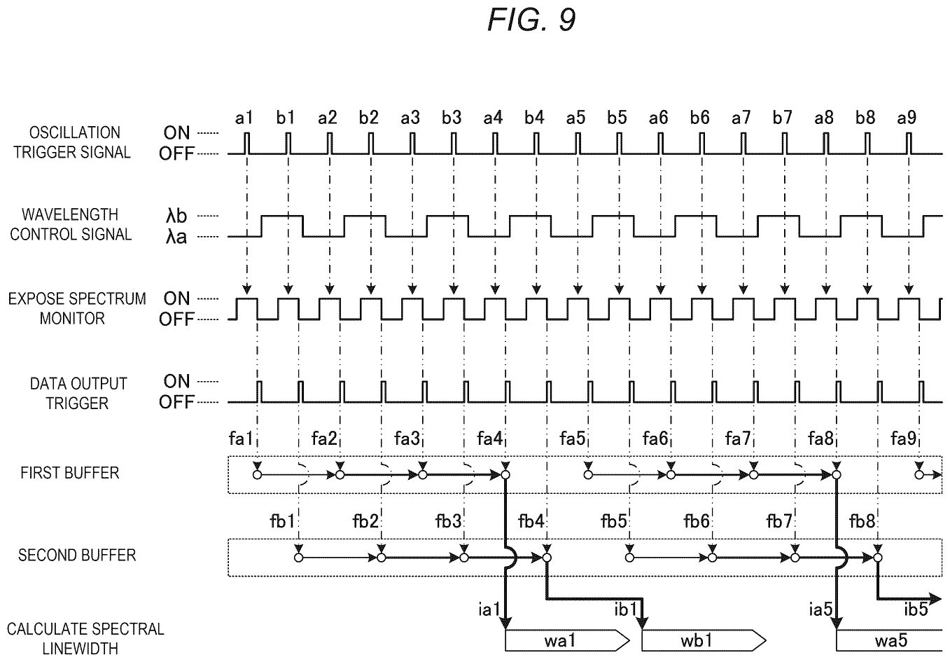

FIG. 9 is a time chart showing a method for measuring the spectral linewidth according to the first embodiment.

The wavelength measurement control processor 50 controls the rotary stage 14e by outputting the wavelength control signal in accordance with the target wavelength that periodically changes from the first wavelength λa to the second wavelength λb and vice versa. The center wavelength of the pulse laser light changes in accordance with the change in the target wavelength. It is assumed that pulses having the first wavelength λa as the target wavelength are a1, a2, . . . , and pulses having the second wavelength λb as the target wavelength are b1, b2, . . . . The following description will be made with reference to the case where the target wavelength is switched from the first wavelength λa to the second wavelength λb and vice versa whenever a pulse advances to another, but the target wavelength is not necessarily switched whenever a pulse advances to another.

The spectrum measurement control processor 60 outputs the data output trigger for each pulse of the pulse laser light. The spectrum monitor 19 outputs fringe waveforms fa1, fb1, fa2, fb2, . . . for each pulse in accordance with the data output trigger.

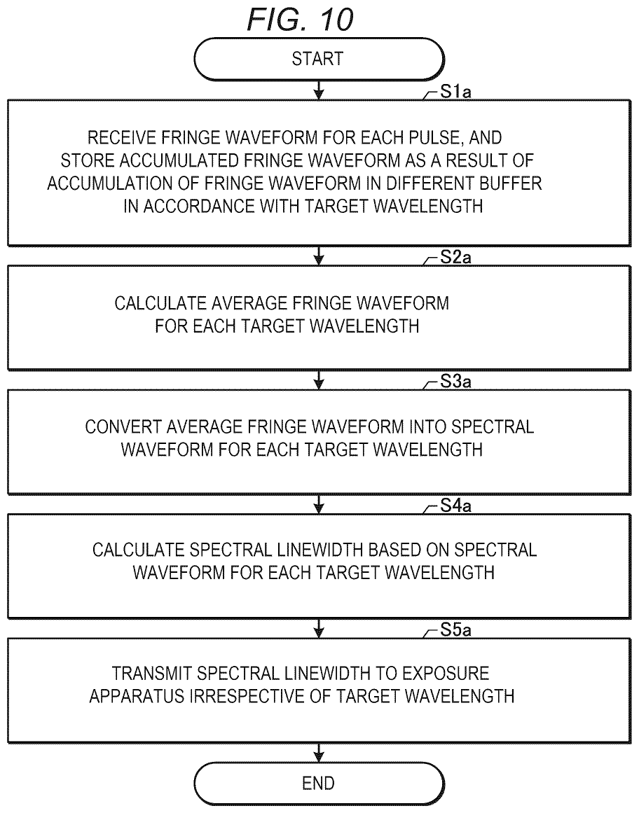

FIG. 10 is a flowchart showing the method for measuring the spectral linewidth according to the first embodiment.

In step S1a, the spectrum measurement control processor 60 receives the fringe waveforms fa1, fb1, fa2, fb2, . . . from the spectrum monitor 19 for each pulse. The fringe waveforms fa1, fb1, fa2, fb2, . . . include the fringe waveforms fa1, fa2, . . . of the pulses a1, a2, . . . each having the first wavelength λa as the target wavelength, and the fringe waveforms fb1, fb2, . . . of the pulses b1, b2, . . . each having the second wavelength λb as the target wavelength, as shown in FIG. 9. The period from the time when the spectrum measurement control processor 60 receives the fringe waveform fa1 of the pulse a1 to the time when the spectrum measurement control processor 60 receives the fringe waveform fa4 of the pulse a4 partially overlaps with the period from the time when the spectrum measurement control processor 60 receives the fringe waveform fb1 of the pulse b1 to the time when the spectrum measurement control processor 60 receives the fringe waveform fb4 of the pulse b4.

Whenever successively receiving a fringe waveform, the spectrum measurement control processor 60 accumulates the fringe waveform to update the accumulated fringe waveform. Whenever updating the accumulated fringe waveform, the spectrum measurement control processor 60 overwrites the previous accumulated fringe waveform and stores the updated accumulated fringe waveform in a different buffer in accordance with the target wavelength. Let ia1 be an accumulated fringe waveform as a result of accumulation of the fringe waveforms fa1, fa2, . . . of the multiple pulses a1, a2, . . . each having the first wavelength λa as the target wavelength, and let ib1 be an accumulated fringe waveform as a result of accumulation of the fringe waveforms fb1, fb2, . . . of the multiple pulses b1, b2, . . . each having the second wavelength λb as the target wavelength. The accumulated fringe waveform ia1 is stored in the first buffer Bu1, and the accumulated fringe waveform ib1 is stored in the second buffer Bu2. The accumulated fringe waveform ia1 corresponds to the first accumulated fringe waveform in the present disclosure, and the accumulated fringe waveform ib1 corresponds to the second accumulated fringe waveform in the present disclosure. Data on the accumulated fringe waveform ia1 is an example of the first accumulated spectrum data in the present disclosure, and data on the accumulated fringe waveform ib1 is an example of the second accumulated spectrum data in the present disclosure. When the number n of accumulated pulses is four, the spectrum measurement control processor 60 accumulates the fringe waveforms fa1 to fa4, accumulates the fringe waveforms fb1 to fb4, and then proceeds to the process in step S2a.

In step S2a, the spectrum measurement control processor 60 calculates an average fringe waveform by dividing the optical intensity of each of the accumulated fringe waveforms ia1 and ib1 by the number n of accumulated pulses. The average fringe waveform is calculated for each target wavelength. The average fringe waveform produced from the accumulated fringe waveform ia1 corresponds to the first average fringe waveform in the present disclosure, and data thereof is an example of the first average spectrum data in the present disclosure. The average fringe waveform produced from the accumulated fringe waveform ib1 corresponds to the second average fringe waveform in the present disclosure, and data thereof is an example of the second average spectrum data in the present disclosure. The data on the accumulated fringe waveform and the data on the average fringe waveform are each an example of the spectrum data in the present disclosure.

In step S3a, the spectrum measurement control processor 60 extracts a portion of the average fringe waveform that corresponds to the free spectral range, and converts the extracted waveform into a spectral waveform. The conversion into a spectral waveform is performed for each target wavelength. A spectral waveform as a result of the conversion of the average fringe waveform produced from the accumulated fringe waveform ia1 corresponds to the first spectral waveform in the present disclosure, and a spectral waveform as a result of the conversion of the average fringe waveform produced from the accumulated fringe waveform ib1 corresponds to the second spectral waveform in the present disclosure.

In step S4a, the spectrum measurement control processor 60 calculates the spectral linewidth based on the spectral waveform. The spectral linewidth is calculated for each target wavelength. For example, a spectral linewidth wa1 is calculated based on the spectral waveform produced from the accumulated fringe waveform ia1, and a spectral linewidth wb1 is calculated based on the spectral waveform produced from the accumulated fringe waveform ib1, as shown in FIG. 9. The spectral linewidth wa1 corresponds to the first spectral linewidth in the present disclosure, and the spectral linewidth wb1 corresponds to the second spectral linewidth in the present disclosure.

The spectrum measurement control processor 60 transmits the spectral linewidth to the laser control processor 30.

In step S5a in FIG. 10, the laser control processor 30 transmits the spectral linewidth to the exposure apparatus 100. The transmission to the exposure apparatus 100 is performed irrespective of the target wavelength. The laser control processor 30 may transmit the spectral linewidth to a lithography control processor that is not shown. The lithography control processor may be a processor that oversees and controls multiple exposure apparatuses. After step S5a, the laser control processor 30 terminates the process of the flowchart.

A pulse a5 and subsequent pulses shown in FIG. 9 are the same as the pulses a1 to a4, and a pulse b5 and subsequent pulses are the same as the pulses b1 to b4.

The calculation of the spectral linewidth based on the fringe waveform received from the spectrum monitor 19 has been described above, and the fringe waveform can also be used to calculate the center wavelength. For example, a first center wavelength can be calculated from the fringe waveform of a pulse having the first wavelength λa as the target wavelength, and a second center wavelength can be calculated from the fringe waveform of a pulse having the second wavelength λb as the target wavelength. The etalon 19b incorporated in the spectrum monitor 19 has a free spectral range narrower than that of the etalon 18b incorporated in the wavelength monitor 18, so that a fringe waveform received from the spectrum monitor 19 can be used to measure the center wavelength with high resolution.

### 2.3 Effects

(1) According to the first embodiment, the laser apparatus la includes the laser oscillator 20, the spectrum monitor 19, the wavelength measurement control processor 50, and the spectrum measurement control processor 60. The laser oscillator 20 includes the rotary stage 14e, and outputs pulse laser light having a center wavelength adjusted by the rotary stage 14e. The spectrum monitor 19 acquires the fringe waveforms fa1, fb1, fa2, fb2, . . . of the pulse laser light. The wavelength measurement control processor 50 controls the rotary stage 14e in such a way that the center wavelength of the pulse laser light changes in accordance with a target wavelength that periodically changes to each of multiple values including the first wavelength λa and the second wavelength 2b. The spectrum measurement control processor 60 calculates the spectral linewidth wa1 from the fringe waveforms fa1, fa2, . . . of the multiple pulses a1, a2, . . . each having the first wavelength λa as the target wavelength, and calculates the spectral linewidth wb1 from the fringe waveforms fb1, fb2, . . . of the multiple pulses b1, b2, . . . each having the second wavelength λb as the target wavelength.

Therefore, the spectral linewidths wa1 and wb1 can be appropriately calculated for each target wavelength.

(2) According to the first embodiment, the spectrum measurement control processor 60 evaluates whether a fringe waveform received from the spectrum monitor 19 is the fringe waveform of a pulse having either the first wavelength λa or the second wavelength λb as the target wavelength based on information representing the content of the control of the rotary stage 14e performed by the wavelength measurement control processor 50.

The configuration described above can accurately determine whether the fringe waveform of the pulse having the first wavelength λa or the second wavelength λb as the target wavelength is produced, and calculate the spectral linewidths wa1 and wb1 for each target wavelength.

(3) According to the first embodiment, the spectrum measurement control processor 60 includes the first buffer Bu1 and the second buffer Bu2. The spectrum measurement control processor 60 causes the first buffer Bu1 to store the accumulated fringe waveform ia1 of the fringe waveforms of the pulses a1, a2, . . . each having the first wavelength λa as the target wavelength, and the second buffer Bu2 to store the accumulated fringe waveform ib1 of the fringe waveforms of the pulses b1, b2, . . . each having the second wavelength λb as the target wavelength.

The multiple buffers Bu1 and Bu2 can therefore be used to efficiently calculate the spectral linewidths wa1 and wb1 for each target wavelength.

(4) According to the first embodiment, whenever receiving the fringe waveforms fa1, fa2, . . . of the pulses a1, a2, . . . each having the first wavelength λa as the target wavelength, the spectrum measurement control processor 60 accumulates the fringe waveforms to update the accumulated fringe waveform ia1, and whenever updating the accumulated fringe waveform ia1, the spectrum measurement control processor 60 overwrites the previous accumulated fringe waveform ia1 and stores the updated accumulated fringe waveform ia1 in the first buffer Bu1. Whenever receiving the fringe waveforms fb1, fb2, . . . of the pulses b1, b2, . . . each having the second wavelength λb as the target wavelength, the spectrum measurement control processor 60 accumulates the fringe waveforms to update the accumulated fringe waveform ib1, and whenever updating the accumulated fringe waveform ib1, the spectrum measurement control processor 60 overwrites the previous accumulated fringe waveform ib1 and stores the updated accumulated fringe waveform ib1 in the second buffer Bu2.

Therefore, whenever fringe waveforms are received, the fringe waveforms are accumulated to update the accumulated fringe waveforms ia1 and ib1, overwrite the previous accumulated fringe waveforms ia1 and ib1, and store the updated accumulated fringe waveforms ia1 and ib1, so that there is no need to store a fringe waveform on a pulse basis, and a storage region necessary for the fringe waveform storage can be reduced.

(5) According to the first embodiment, whenever successively receiving the fringe waveforms fa1 to fa4 of the pulses a1 to a4 each having the first wavelength Na as the target wavelength, the spectrum measurement control processor 60 accumulates the fringe waveforms fa1 to fa4 to update the accumulated fringe waveform ia1, and whenever updating the accumulated fringe waveform ia1, the spectrum measurement control processor 60 causes the first buffer Bu1 to store the updated accumulated fringe waveform ia1. Whenever successively receiving the fringe waveforms fb1 to fb4 of the pulses b1 to b4 each having the second wavelength λb as the target wavelength, the spectrum measurement control processor 60 accumulates the fringe waveforms fb1 to fb4 to update the accumulated fringe waveform ib1, and whenever updating the accumulated fringe waveform ib1, the spectrum measurement control processor 60 causes the second buffer Bu2 to store the updated accumulated fringe waveform ib1. The period from the time when the spectrum measurement control processor 60 receives the fringe waveform fa1 of the pulse a1 to the time when the spectrum measurement control processor 60 receives the fringe waveform fa4 of the pulse a4 partially overlaps with the period from the time when the spectrum measurement control processor 60 receives the fringe waveform fb1 of the pulse b1 to the time when the spectrum measurement control processor 60 receives the fringe waveform fb4 of the pulse b4.

Therefore, since one of the accumulated fringe waveform ia1 stored in the first buffer Bu1 and the accumulated fringe waveform ib1 stored in the second buffer Bu2 can be updated with the other held in the other buffer, the accumulated fringe waveforms ia1 and ib1 for each target wavelength can be efficiently updated.

(6) According to the first embodiment, the spectrum measurement control processor 60 accumulates the fringe waveforms fa1, fa2, . . . of the multiple pulses a1, a2, . . . each having the first wavelength λa as the target wavelength to calculate the first accumulated spectrum data, and calculates the spectral linewidth wa1 from the first accumulated spectrum data. The spectrum measurement control processor 60 accumulates the fringe waveforms fb1, fb2, . . . of the multiple pulses b1, b2, . . . each having the second wavelength λb as the target wavelength to calculate the second accumulated spectrum data, and calculates the spectral linewidth wb1 from the second accumulated spectrum data. When the spectrum monitor 19 converts a fringe waveform into a spectral waveform, the spectrum measurement control processor 60 may accumulate the spectral waveform for each target wavelength to calculate each of the first and second accumulated spectrum data.

Therefore, since a fringe waveform or a spectral waveform is accumulated for each target wavelength, the spectral linewidths wa1 and wb1 can each be appropriately calculated for each target wavelength.

(7) According to the first embodiment, the spectrum measurement control processor 60 averages the fringe waveforms fa1, fa2, . . . of the multiple pulses a1, a2, . . . each having the first wavelength λa as the target wavelength to calculate the first average spectrum data, and calculates the spectral linewidth wa1 from the first average spectrum data. The spectrum measurement control processor 60 averages the fringe waveforms fb1, fb2, . . . of the multiple pulses b1, b2, . . . each having the second wavelength λb as the target wavelength to calculate the second average spectrum data, and calculates the spectral linewidth wb1 from the second average spectrum data. When the spectrum monitor 19 converts fringe waveforms into spectral waveforms, the spectrum measurement control processor 60 may average the spectral waveforms for each target wavelength to calculate the first and second average spectrum data.

Therefore, since the fringe waveforms or the spectral waveforms are averaged for each target wavelength, the spectral linewidths wa1 and wb1 can be appropriately calculated for each target wavelength.

(8) According to the first embodiment, the spectrum measurement control processor 60 receives the fringe waveforms fa1, fb1, fa2, fb2, . . . from the spectrum monitor 19 on a pulse basis. The spectrum measurement control processor 60 accumulates the fringe waveforms fa1, fa2, . . . of the multiple pulses a1, a2, . . . each having the first wavelength λa as the target wavelength to calculate the accumulated fringe waveform ia1, calculates the first spectral waveform from the accumulated fringe waveform ia1, and calculates the spectral linewidth wa1 from the first spectral waveform. The spectrum measurement control processor 60 accumulates the fringe waveforms fb1, fb2, . . . of the multiple pulses b1, b2, . . . each having the second wavelength λb as the target wavelength to calculate the accumulated fringe waveform ib1, calculates the second spectral waveform from the accumulated fringe waveform ib1, and calculates the spectral linewidth wb1 from the second spectral waveform.

Therefore, since the fringe waveforms are accumulated for each target wavelength, the spectral linewidths wa1 and wb1 can be appropriately calculated for each target wavelength.

(9) According to the first embodiment, the spectrum measurement control processor 60 averages the fringe waveforms fa1, fa2, . . . of the multiple pulses a1, a2, . . . each having the first wavelength λa as the target wavelength to calculate the first average fringe waveform, calculates the first spectral waveform from the first average fringe waveform, and calculates the spectral linewidth wa1 from the first spectral waveform. The spectrum measurement control processor 60 averages the fringe waveforms fb1, fb2, . . . of the multiple pulses b1, b2, . . . each having the second wavelength λb as the target wavelength to calculate the second average fringe waveform, calculates the second spectral waveform from the second average fringe waveform, and calculates the spectral linewidth wb1 from the second spectral waveform.

Therefore, since the fringe waveforms are averaged for each target wavelength, the spectral linewidths wa1 and wb1 can be appropriately calculated for each target wavelength.

(10) According to the first embodiment, the laser control processor 30 incorporated in the laser apparatus 1a does not distinguish the spectral linewidth wa1 for the first wavelength λa from the spectral linewidth wb1 for the second wavelength λb and transmits the spectral linewidths wa1 and wb1 to the exposure apparatus 100.

It is not therefore necessary to transmit information for distinguishing the target wavelengths from each other, so that the load on a communication apparatus can be reduced.

(11) According to the first embodiment, the spectrum measurement control processor 60 calculates the first center wavelength from the fringe waveforms fa1, fa2, . . . of the multiple pulses a1, a2, . . . each having the first wavelength λa as the target wavelength, and calculates the second center wavelength from the fringe waveforms fb1, fb2, . . . of the multiple pulses b1, b2, . . . each having the second wavelength λb as the target wavelength.

The fringe waveforms fa1, fb1, fa2, fb2, . . . generated in the spectrum monitor 19 can therefore also be used to calculate the center wavelengths. The thus calculated center wavelengths can also be used to calibrate the wavelength monitor 18.

As for the other points, the first embodiment is the same as Comparative Example.

### 3. Embodiment using Fringe Waveforms of Pulses Excluding Start Pulses of Burst

### 3.1 Operation

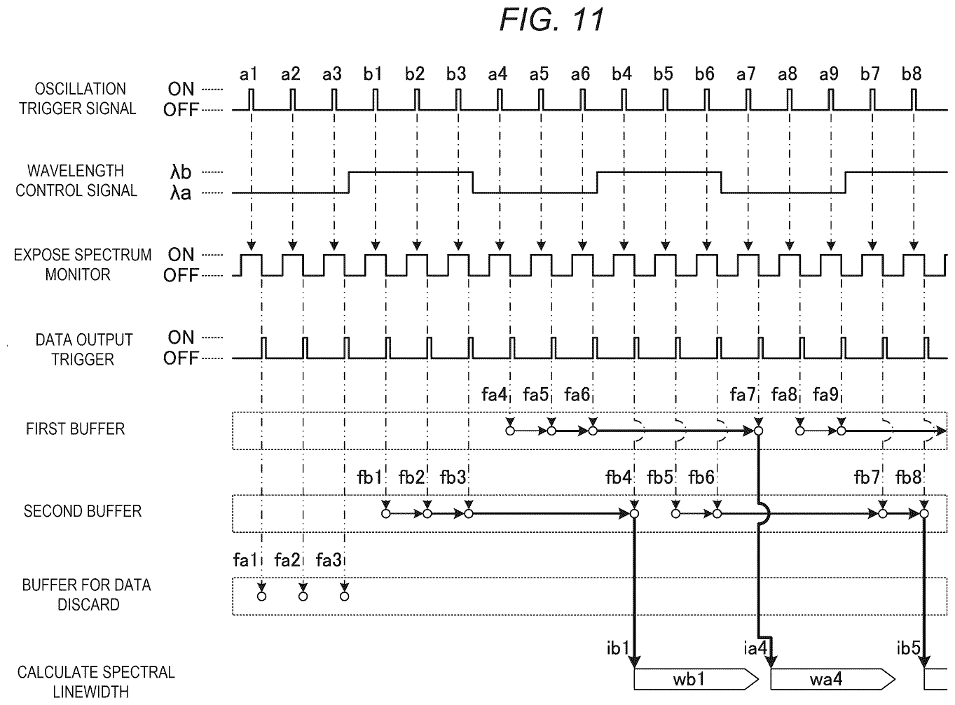

FIG. 11 is a time chart showing a method for measuring the spectral linewidth according to a second embodiment. The laser apparatus la according to the second embodiment differs in configuration from that according to the first embodiment in that the memory 62 of the spectrum measurement control processor 60 includes a buffer that is not shown but used to discard data, but is the same as the laser apparatus 1a according to the first embodiment in terms of other points.

The wavelength measurement control processor 50 generates the wavelength control signal that switches the target wavelength from the first wavelength λa to the second wavelength λb and vice versa whenever three pulses advance to another three pulses. The target wavelength is, however, not necessarily switched whenever three pulses advance to another three pulses.

The spectrum measurement control processor 60 outputs the data output trigger for each pulse of the pulse laser light, as in the same manner described with reference to FIG. 9. The spectrum monitor 19 outputs the fringe waveforms fa1, fa2, . . . and fb1, fb2, . . . for each pulse in accordance with the data output trigger.

The spectrum measurement control processor 60 receives the fringe waveforms fa1, fa2, . . . and fb1, fb2, . . . from the spectrum monitor 19 for each pulse, as in step S1a in FIG. 10.

The spectrum measurement control processor 60 causes the buffer that is not shown but used to discard data to store the fringe waveforms fa1, fa2, and fa3 of the start pulses a1, a2, and a3 of the burst of the pulse laser light output in the burst oscillation. Although the number of pulses stored in the buffer for data discard is set at three, but not necessarily.

Data on the fringe waveforms fa1, fa2, and fa3 are temporarily stored in the buffer and then discarded. The data may instead be discarded without being temporarily stored in the buffer. Still instead, the data may be stored as log data separately in a nonvolatile memory that is not shown.

The spectrum measurement control processor 60 accumulates the fringe waveforms fb1, fb2, fb3, and fb4 of the pulses b1, b2, b3, and b4, and causes the second buffer Bu2 to store the accumulated fringe waveform ib1.

The spectrum measurement control processor 60 accumulates the fringe waveforms fa4, fa5, fa6, and fa7 of pulses a4, a5, a6, and a7, and causes the first buffer Bu1 to store an accumulated fringe waveform ia4.

The spectrum measurement control processor 60 calculates the spectral linewidth based on the spectral waveform, as in step S4a in FIG. 10. Note, however, that the spectral linewidth is calculated with the fringe waveforms fa1, fa2, and fa3 of the start pulses a1, a2, and a3 of the burst excluded.

The spectral linewidth is calculated for each target wavelength. For example, the spectral linewidth wb1 is calculated based on the spectral waveform produced from the accumulated fringe waveform ib1, and a spectral linewidth wa4 is calculated based on the spectral waveform produced from the accumulated fringe waveform ia4, as shown in FIG. 11.

The pulse b5 and the subsequent pulses are the same as the pulses b1 to b4, and a pulse a8 and subsequent pulses are the same as the pulses a4 to a7.

### 3.2 Effects

(12) According to the second embodiment, the laser oscillator 20 is configured to perform the burst oscillation multiple times, which includes the first burst oscillation and the second burst oscillation following the first burst oscillation, to output the pulse laser light. The spectrum measurement control processor 60 calculates the spectral linewidths wb1 and wa4 with the fringe waveforms fa1 to fa3 of the start pulses a1 to a3 of each of the bursts excluded.

The fringe waveforms fa1 to fa3 of the pulses a1 to a3, which are not used as the exposure light in the exposure apparatus 100, are therefore excluded, so that the load of the calculation of the spectral linewidth can be reduced.

(13) According to the second embodiment, the spectrum measurement control processor 60 discards the excluded fringe waveforms fa1 to fa3.

Discarding the fringe waveforms fa1 to fa3 can therefore reduce a storage region necessary for the fringe waveform storage.

(14) According to the second embodiment, the spectrum measurement control processor 60 separately stores the excluded fringe waveforms fa1 to fa3.

Storing the fringe waveforms fa1 to fa3 not having been used to calculate the spectral linewidths therefore allows the waveforms to be used for data analysis in the event of failure.

As for the other points, the second embodiment is the same as the first embodiment.

### 4. Embodiment using Fringe Waveforms of Consecutive Pulses

### 4.1 Operation

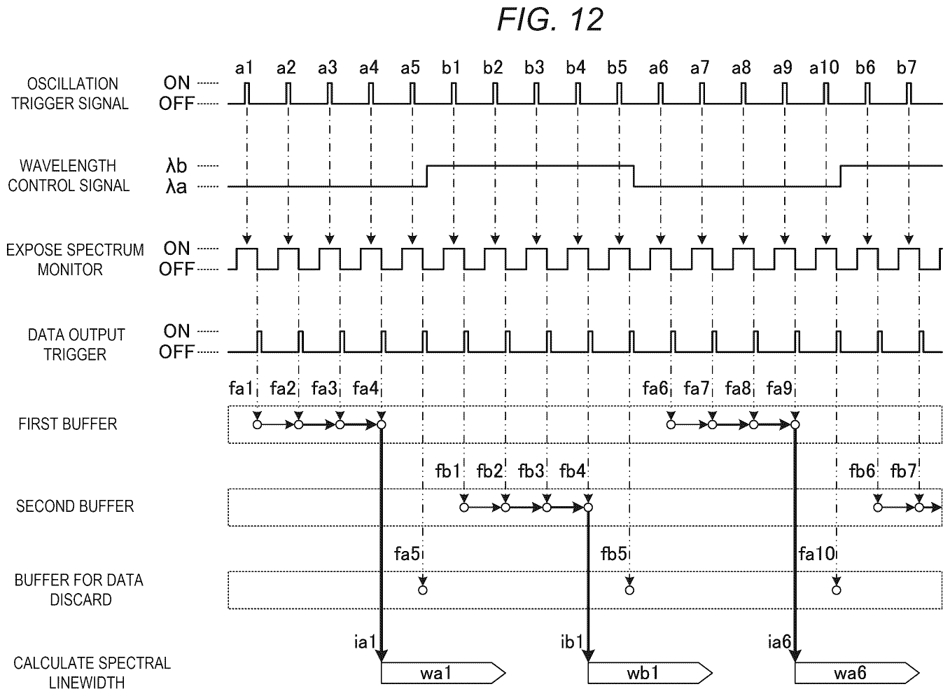

FIG. 12 is a time chart showing a method for measuring the spectral linewidth according to a third embodiment. The configuration of the laser apparatus la according to the third embodiment is the same as that according to the second embodiment.

The wavelength measurement control processor 50 generates the wavelength control signal that switches the target wavelength from the first wavelength λa to the second wavelength λb and vice versa whenever five pulses advance to another five pulses. That is, one cycle of the change in the wavelength includes successively outputting a first number of pulses each having the first wavelength λa and successively outputting a second number of pulses each having the second wavelength λb, and the first and second numbers are, for example, five. The target wavelength is thus switched whenever a set of pulses the number of which is greater than the number n of accumulated pulses, for example, four pulses, advances to another set.

The spectrum measurement control processor 60 outputs the data output trigger for each pulse of the pulse laser light, as in the same manner described with reference to FIG. 9. The spectrum monitor 19 outputs the fringe waveforms fa1, fa2, . . . and fb1, fb2, . . . for each pulse in accordance with the data output trigger.

The spectrum measurement control processor 60 receives the fringe waveforms fa1, fa2, . . . and fb1, fb2, . . . from the spectrum monitor 19 for each pulse, as in step S1a in FIG. 10.

Whenever successively receiving the fringe waveforms fa1, fa2, fa3, and fa4 of the pulses a1, a2, a3, and a4, the spectrum measurement control processor 60 accumulates the fringe waveforms fa1, fa2, fa3, and fa4 to update the accumulated fringe waveform ia1. Whenever updating the accumulated fringe waveform ia1, the spectrum measurement control processor 60 overwrites the previous accumulated fringe waveform ia1 and causes the first buffer Bu1 to store the updated accumulated fringe waveform ia1.

Whenever successively receiving the fringe waveforms fb1, fb2, fb3, and fb4 of the pulses b1, b2, b3, and b4, the spectrum measurement control processor 60 accumulates the fringe waveforms fb1, fb2, fb3, and fb4 to update the accumulated fringe waveform ib1. Whenever updating the accumulated fringe waveform ib1, the spectrum measurement control processor 60 overwrites the previous accumulated fringe waveform ib1 and causes the second buffer Bu2 to store the updated accumulated fringe waveform ib1.

The spectrum measurement control processor 60 causes the buffer that is not shown but used to discard data to store the fringe waveforms fa5 and fb5 of the pulses a5 and b5, which are remaining pulses excluding four pulses corresponding to the number n of accumulated pulses out of five pulses successively output without switching the target wavelength.

Data on the fringe waveforms fa5 and fb5 are temporarily stored in the buffer and then discarded. The data may instead be discarded without being temporarily stored in the buffer. Still instead, the data may be stored as log data separately in a nonvolatile memory that is not shown.

The spectrum measurement control processor 60 calculates the spectral linewidth based on the spectral waveform, as in step S4a in FIG. 10. The configuration described above excludes the fringe waveform fa5 of the pulse a5 other than a third number of pulses a1 to a4 corresponding to the number n of accumulated pulses out of the five pulses a1 to a5 each having the first wavelength λa as the target wavelength and successively output, and the spectral linewidth wa1 is calculated based on the fringe waveforms fa1 to fa4 of the third number of pulses a1 to a4. The configuration described above further excludes the fringe waveform fb5 of the pulse b5 other than a fourth number of pulses b1 to b4 corresponding to the number n of accumulated pulses out of the five pulses b1 to b5 each having the second wavelength λb as the target wavelength and successively output, and the spectral linewidth wb1 is calculated based on the fringe waveforms fb1 to fb4 of the fourth number of pulses b1 to b4. The spectral linewidth is thus calculated for each target wavelength. The third and fourth numbers are, for example, four.

The period for which the spectral linewidth wa1 is calculated based on the accumulated fringe waveform ia1 stored in the first buffer Bu1 partially overlaps with the period from the time when the spectrum measurement control processor 60 receives the fringe waveform fb1 of the pulse b1 to the time when the spectrum measurement control processor 60 receives the fringe waveform fb4 of the pulse b4. Even when the periods partially overlap with each other, the data on the accumulated fringe waveform ib1 can be stored in the second buffer Bu2 with the data on the accumulated fringe waveform ia1 stored in the first buffer Bu1.

The period for which the spectral linewidth wb1 is calculated based on the accumulated fringe waveform ib1 stored in the second buffer Bu2 partially overlaps with the period from the time when the spectrum measurement control processor 60 receives the fringe waveform fa6 of the pulse a6 to the time when the spectrum measurement control processor 60 receives a fringe waveform fa9 of a pulse a9. Even when the periods partially overlap with each other, the data on the accumulated fringe waveform ia6 can be stored in the first buffer Bu1 with data on the accumulated fringe waveform ib1 stored in the second buffer Bu2.

The pulse a6 and the subsequent pulses are the same as the pulses a1 to a5, and a pulse b6 and subsequent pulses are the same as the pulses b1 to b5.

### 4.2 Effects

(15) According to the third embodiment, one cycle of the periodic change in the target wavelength includes successively outputting the first number of pulses a1 to a5 each having the first wavelength λa and successively outputting the second number of pulses b1 to b5 each having the second wavelength λb. The spectrum measurement control processor 60 excludes the fringe waveform fa5 of the pulse a5 other than the third number of pulses a1 to a4 out of the first number of pulses a1 to a5, and calculates the spectral linewidth wa1 based on the fringe waveforms fa1 to fa4 of the third number of pulses a1 to a4 out of the first number of pulses a1 to a5. The spectrum measurement control processor 60 excludes the fringe waveform fb5 of the pulse b5 other than the fourth number of pulses b1 to b4 out of the second number of pulses b1 to b5, and calculates the spectral linewidth wb1 based on the fringe waveforms fb1 to fb4 of the fourth number of pulses b1 to b4 out of the second number of pulses b1 to b5.

The pulses having the same target wavelength and successively output therefore have little fluctuation in the fringe waveform, so that the fringe waveforms of the pulses can be used to appropriately calculate the spectral linewidths wa1 and wb1.

(16) According to the third embodiment, the spectrum measurement control processor 60 discards the excluded fringe waveforms fa5 and fb5.

Discarding the fringe waveforms fa5 and fb5 can therefore reduce a storage region necessary for the fringe waveform storage.

(17) According to the third embodiment, the spectrum measurement control processor 60 separately stores the excluded fringe waveforms fa5 and fb5.

Storing the fringe waveforms fa5 and fb5 not having been used to calculate the spectral linewidths therefore allows the waveforms to be used for data analysis in the event of failure.

(18) According to the third embodiment, whenever successively receiving the fringe waveforms fa1 to fa4 of the pulses a1 to a4 each having the first wavelength Na as the target wavelength, the spectrum measurement control processor 60 accumulates the fringe waveforms fa1 to fa4 to update the accumulated fringe waveform ia1, and whenever updating the accumulated fringe waveform ia1, the spectrum measurement control processor 60 causes the first buffer Bu1 to store the updated accumulated fringe waveform ia1. Whenever successively receiving the fringe waveforms fb1 to fb4 of the pulses b1 to b4 each having the second wavelength λb as the target wavelength, the spectrum measurement control processor 60 accumulates the fringe waveforms fb1 to fb4 to update the accumulated fringe waveform ib1, and whenever updating the accumulated fringe waveform ib1, the spectrum measurement control processor 60 causes the second buffer Bu2 to store the updated accumulated fringe waveform ib1. The period for which the spectral linewidth wa1 is calculated based on the accumulated fringe waveform ia1 stored in the first buffer Bu1 partially overlaps with the period from the time when the spectrum measurement control processor 60 receives the fringe waveform fb1 of the pulse b1 to the time when the spectrum measurement control processor 60 receives the fringe waveform fb4 of the pulse b4.

The data on the accumulated fringe waveform ib1 can therefore be stored in the second buffer Bu2 with the data on the accumulated fringe waveform ia1 stored in the first buffer Bu1, and the calculation of the spectral linewidth wa1 and the accumulation of the fringe waveforms fb1 to fb4 can be efficiently performed.

As for the other points, the third embodiment is the same as the first embodiment.

### 5. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a laser oscillator including a wavelength adjuster and configured to output pulse laser light having a center wavelength adjusted by the wavelength adjuster;
a spectrum monitor configured to generate data on a spectrum of the pulse laser light; and
a processor configured to
control the wavelength adjuster in such a way that the center wavelength of the pulse laser light changes in accordance with a target wavelength that periodically changes to each of multiple values including first and second wavelengths,
calculate a first spectral linewidth from data on spectra of multiple pulses each having the first wavelength as the target wavelength, and
calculate a second spectral linewidth from data on spectra of multiple pulses each having the second wavelength as the target wavelength.

2. The laser apparatus according to claim 1,
wherein the processor is configured to evaluate whether the spectral data received from the spectrum monitor is data on a spectrum of a pulse having a specific value of the multiple values as the target wavelength based on information representing a content of control of the wavelength adjuster performed by the processor.

3. The laser apparatus according to claim 1,
wherein the processor
includes first and second buffers, and is configured to
cause the first buffer to store data on a spectrum of a pulse having the first wavelength as the target wavelength, and
cause the second buffer to store data on a spectrum of a pulse having the second wavelength as the target wavelength.

4. The laser apparatus according to claim 1,
wherein the processor
includes first and second buffers, and is configured to
accumulate data on a spectrum of a pulse having the first wavelength as the target wavelength whenever receiving the data to update a first accumulated spectrum data, overwrite a previous first accumulated spectrum data whenever updating the first accumulated spectrum data, and cause the first buffer to store the updated first accumulated spectrum data, and
accumulate data on a spectrum of a pulse having the second wavelength as the target wavelength whenever receiving the data to update a second accumulated spectrum data, overwrite a previous second accumulated spectrum data whenever updating the second accumulated spectrum data, and cause the second buffer to store the updated second accumulated spectrum data.

5. The laser apparatus according to claim 1,
wherein the processor
includes first and second buffers, and is configured to
accumulate data on spectra of a1-th to an-th pulses each having the first wavelength as the target wavelength whenever successively receiving the data to update a first accumulated spectrum data, and cause the first buffer to store the updated first accumulated spectrum data whenever updating the first accumulated spectrum data, and
accumulate data on spectra of b1-th to bn-th pulses each having the second wavelength as the target wavelength whenever successively receiving the data to update a second accumulated spectrum data, and cause the second buffer to store the updated second accumulated spectrum data whenever updating the second accumulated spectrum data, and
a period from a time when the processor receives the data on the spectrum of the a1-th pulse to a time when the processor receives the data on the spectrum of the an-th pulse partially overlaps with a period from a time when the processor receives the data on the spectrum of the b1-th pulse to a time when the processor receives the data on the spectrum of the bn-th pulse.

6. The laser apparatus according to claim 1,
wherein the processor is configured to
accumulate data on spectra of multiple pulses each having the first wavelength as the target wavelength to calculate a first accumulated spectrum data, and calculate the first spectral linewidth from the first accumulated spectrum data, and
accumulate data on spectra of multiple pulses each having the second wavelength as the target wavelength to calculate a second accumulated spectrum data, and calculate the second spectral linewidth from the second accumulated spectrum data.

7. The laser apparatus according to claim 1,
wherein the processor is configured to
average data on spectra of multiple pulses each having the first wavelength as the target wavelength to calculate a first average spectrum data, and calculates the first spectral linewidth from the first average spectrum data, and
average data on spectra of multiple pulses each having the second wavelength as the target wavelength to calculate a second average spectrum data, and calculates the second spectral linewidth from the second average spectrum data.

8. The laser apparatus according to claim 1,
wherein the processor is configured to
receive the spectrum data containing a fringe waveform on a pulse basis from the spectrum monitor,
accumulate fringe waveforms of multiple pulses each having the first wavelength as the target wavelength to calculate a first accumulated fringe waveform, calculate a first spectral waveform from the first accumulated fringe waveform, and calculate the first spectral linewidth from the first spectral waveform, and
accumulate fringe waveforms of multiple pulses each having the second wavelength as the target wavelength to calculate a second accumulated fringe waveform, calculate a second spectral waveform from the second accumulated fringe waveform, and calculate the second spectral linewidth from the second spectral waveform.

9. The laser apparatus according to claim 1,
wherein the processor is configured to
receive the spectrum data containing a fringe waveform on a pulse basis from the spectrum monitor,
average fringe waveforms of multiple pulses each having the first wavelength as the target wavelength to calculate a first average fringe waveform, calculate a first spectral waveform from the first average fringe waveform, and calculate the first spectral linewidth from the first spectral waveform, and
average fringe waveforms of multiple pulses each having the second wavelength as the target wavelength to calculate a second average fringe waveform, calculate a second spectral waveform from the second average fringe waveform, and calculate the second spectral linewidth from the second spectral waveform.

10. The laser apparatus according to claim 1,
wherein the processor is configured not to distinguish a spectral linewidth for the first wavelength from a spectral linewidth for the second wavelength but to transmit the spectral linewidths to an external apparatus.

11. The laser apparatus according to claim 1,
wherein the processor is configured to
calculate a first center wavelength from data on spectra of multiple pulses each having the first wavelength as the target wavelength, and
calculate a second center wavelength from data on spectra of multiple pulses each having the second wavelength as the target wavelength.

12. The laser apparatus according to claim 1,
wherein the laser oscillator is configured to output the pulse laser light by performing burst oscillation multiple times, the burst oscillation including first burst oscillation and second burst oscillation following the first burst oscillation, and
the processor is configured to calculate the first and second spectral linewidths with data on a spectrum of a start pulse of each of the bursts excluded.

13. The laser apparatus according to claim 12,
wherein the processor is configured to discard the excluded spectrum data.

14. The laser apparatus according to claim 12,
wherein the processor is configured to separately store the excluded spectrum data.

15. The laser apparatus according to claim 1,
wherein one cycle of a periodic change in the target wavelength includes successively outputting a first number of pulses each having the first wavelength and successively outputting a second number of pulses each having the second wavelength,
the processor is configured to
exclude data on a spectrum of a pulse other than a third number of pulses out of the first number of pulses, and calculate the first spectral linewidth based on data on spectra of the third number of pulses out of the first number of pulses, and
exclude data on a spectrum of a pulse other than a fourth number of pulses out of the second number of pulses, and calculate the second spectral linewidth based on data on spectra of the fourth number of pulses out of the second number of pulses.

16. The laser apparatus according to claim 15,
wherein the processor is configured to discard the excluded spectrum data.

17. The laser apparatus according to claim 15,
wherein the processor is configured to separately store the excluded spectrum data.

18. The laser apparatus according to claim 1,
wherein the processor
includes first and second buffers, and is configured to
accumulate data on spectra of a1-th to an-th pulses each having the first wavelength as the target wavelength whenever successively receiving the data to update a first accumulated spectrum data, and cause the first buffer to store the updated first accumulated spectrum data whenever updating the first accumulated spectrum data, and
accumulate data on spectra of b1-th to bn-th pulses each having the second wavelength as the target wavelength whenever successively receiving the data to update a second accumulated spectrum data, and cause the second buffer to store the updated second accumulated spectrum data whenever updating the second accumulated spectrum data, and
a period for which the first spectral linewidth is calculated based on the first accumulated spectrum data stored in the first buffer partially overlaps with a period from a time when the processor receives the data on the spectrum of the b1-th pulse to a time when the processor receives the data on the spectrum of the bn-th pulse.

19. A method for measuring a spectral linewidth, the method comprising:
changing a center wavelength of pulse laser light in accordance with a target wavelength that periodically changes to each of multiple values including first and second wavelengths;
calculating a first spectral linewidth from data on spectra of multiple pulses each having the first wavelength as the target wavelength; and
calculating a second spectral linewidth from data on spectra of multiple pulses each having the second wavelength as the target wavelength.

20. A method for manufacturing electronic device, the method comprising:
generating pulse laser light by using a laser apparatus;
outputting the pulse laser light to an exposure apparatus; and
exposing a photosensitive substrate with the pulse laser light in the exposure apparatus to manufacture the electronic devices,
the laser apparatus including
a laser oscillator including a wavelength adjuster and configured to output the pulse laser light having a center wavelength adjusted by the wavelength adjuster,
a spectrum monitor configured to generate data on a spectrum of the pulse laser light, and
a processor configured to
control the wavelength adjuster in such a way that the center wavelength of the pulse laser light changes in accordance with a target wavelength that periodically changes to each of multiple values including first and second wavelengths,
calculate a first spectral linewidth from data on spectra of multiple pulses each having the first wavelength as the target wavelength, and
calculate a second spectral linewidth from data on spectra of multiple pulses each having the second wavelength as the target wavelength.
